(19) United States
(12) Patent Application Publication
(10) Pub. No.: US 2002/0179012 A1
(43) Pub. Date: Dec. 5, 2002

(54) Film forming apparatus, electron source manufacturing apparatus, and manufacturing methods using the apparatuses

(76) Inventors: Kazumasa Takatsu, Tokyo (JP); Masahiro Kanai, Tokyo (JP)

Correspondence Address: FITZPATRICK CELLA HARPER & SCINTO, 30 ROCKEFELLER PLAZA, NEW YORK, NY, 10112, US

(21) Appl. No.: 10/144,720

(22) Filed: May 15, 2002

(30) Foreign Application Priority Data
May 15, 2001 (JP) 144315/2001(PAT.)
May 13, 2002 (JP) 137230/2002(PAT.)

(51) Int. Cl. C23C 16/00

(52) U.S. Cl. 118/715

(57) ABSTRACT

A film forming apparatus for forming a film on a substrate is provided, the apparatus including gas introduction unit including a nozzle for jetting a gas for forming the film toward a surface of the substrate and an inlet for introducing the gas, the gas introduction unit having a plurality of nozzles connected to the one inlet by divergent paths.

### BACKGROUND OF THE INVENTION

1. Field of the Invention

The present invention relates to a film forming apparatus, an apparatus for manufacturing an electron source, and manufacturing methods using the apparatuses.

2. Related Background Art

Electron-emitting devices heretofore known are generally grouped into two types: the thermionic emission type and the cold emission type. Cold-emission devices include field-emission (FE) devices, metal-insulator-metal (MIM) devices, and surface conduction electron-emitting devices.

For example, a FE-type device, such as the one disclosed by W. P. Dyke and W. W. Dolan in “Field Emission”, Advance in Electron Physics, 8,89 (1956), or the one disclosed by C. A. Spindt in “Physical Properties of thin-film filed emission cathodes with molybdenum cones”, J. Appl. phys. 47, 5248 (1976), is known.

A MIM-type device, such as the one disclosed by C. A. Mead in “Operation of Tunnel-Emission Devices”, J. Appl. Phys. 32,646 (1961), is known.

A surface conduction electron-emitting device, such as the one disclosed by M. I. Elinson, Radio Eng. Electron Phys. 10, 1290 (1965), is known.

A surface conduction electron-emitting device is based on a phenomenon in which electrons are emitted from a small-area thin film formed on a substrate when a current is caused to flow through the film parallel to the film surface. The applicant of the present invention has proposed a number of surface conduction electron-emitting devices novel in construction and various applications of the devices. The basic constructions of the devices and the methods of manufacturing the devices have been disclosed, for example, in Japanese Patent Applications Laid-open No. 7-235255, No. 8-171849, etc. A typical example of the proposed surface conduction electron-emitting devices has such a construction that a conductive film for forming an electron-emitting region is formed on a substrate so as to connect a pair of device electrodes on the substrate, and the electron-emitting region is formed by performing an energization process called forming in advance and by performing an activation step after forming.

Forming is a process for forming a fissure as a portion in an electrically high-resistance state in the electron-emitting region forming thin film in such a manner that a voltage is applied to opposite ends of the thin film to cause a current to flow through the film to locally break, deform or denature the film.

The activation step is a process for forming a carbon coating in the vicinity of the fissure in the electron-emitting region forming thin film in such a manner that a voltage is applied to the opposite ends of the thin film to cause a current to flow through the film in a vacuum atmosphere including an organic compound. In the completed device, electrons are emitted from portions in the vicinity of the fissure.

The above-described surface conduction electron-emitting device is advantageous in that a large number of the devices can be arrayed and formed throughout a large area because its structure is simple and because it can be easily manufactured. Various studies have been made to utilize the advantages of the characteristics of the surface conduction electron-emitting device. For example, use of the device in a charge beam source or an image forming apparatus such as a display may be mentioned. An example of an array of a multiplicity of surface conduction electron-emitting devices formed as an electron source may be mentioned in which a multiplicity of rows of surface conduction electron-emitting devices are arranged in parallel with each other, opposite ends of each device being wired to desired points.

In the process of manufacturing the conventional surface conduction electron-emitting device, a device having a pair of electrodes and a conductive film formed is placed in a vacuum atmosphere and undergoes a forming step, and a process step (activation step) is thereafter performed in which a gas containing at least one element in common with a new deposit on the electron-emitting region is introduced into the vacuum atmosphere, and a pulse voltage selected as desired is applied for several minutes to several ten minutes. This process step is effective in improving a characteristic of the electron-emitting device. By this step, the electron emission current characteristic of the electron-emitting device is improved, that is, electron emission current Ie is largely increased with respect to the voltage, while the threshold value is maintained.

The above-described activation step, however, has a problem described below.

The activation step in which carbon and a carbon compound are deposited on the electron-emitting region and in the vicinity of the same is performed by decomposing an organic material adsorbed from the atmosphere onto the device substrate. If the number of devices simultaneously processed is increased, the amount of the organic material decomposed and consumed on the electron source substrate per unit time is also increased, so that the concentration of the organic material in the atmosphere varies and the carbon film forming rate is reduced or the uniformity of the carbon film forming rate with respect to the location on the surface of the electron source substrate is reduced, resulting in failure to obtain the desired uniformity of the electron source.

### SUMMARY OF THE INVENTION

Therefore, an object of the present invention is to provide a film forming apparatus capable of forming a film having improved crystallinity and a method using the apparatus.

Also, an object of the present invention is to provide an electron source manufacturing apparatus which enables manufacture of an electron source having improved electron-emitting characteristics and a method of manufacturing an electron source using the apparatus.

Also, an object of the present invention is to provide an electron source manufacturing apparatus for forming a carbon film or carbon compound film having improved crystallinity by an electron source activation step to enable manufacture of an electron source having improved electron-emitting characteristics and a method of manufacturing an electron source using the apparatus.

The present invention relates to a film forming apparatus for forming a film on a substrate, the apparatus characterized by comprising gas introduction means including a nozzle for jetting a gas for forming the film toward a surface of the substrate and an inlet for introducing the gas, the gas introduction means having a plurality of the nozzles connected to the one inlet by divergent paths.

Also, the present invention relates to a film forming method of forming a film on a substrate, the method characterized by comprising using the above-described apparatus.

Also, the present invention relates to an apparatus for manufacturing an electron source in which an electron-emitting function is provided in a member provided on a substrate, the apparatus characterized by comprising gas introduction means including a nozzle for jetting a gas for providing the electron-emitting function toward a surface of the substrate and an inlet for introducing the gas, the gas introduction means having a plurality of the nozzles connected to the one inlet by divergent paths.

Also, the present invention relates to a method of manufacturing an electron source, the method comprising a step of providing an electron-emitting function to a member provided on a substrate, characterized in that the step of providing the electron-emitting function is performed by using the above-described apparatus.

### BRIEF DESCRIPTION OF THE DRAWINGS

FIG. 1 is a perspective view of a portion of an electron source manufacturing apparatus in an embodiment of the present invention, a portion along the periphery of an electron source substrate being cut away;

FIG. 2 is a schematic sectional view and a piping diagram of the entire structure of the electron source manufacturing apparatus shown in FIG. 1;

FIG. 3 is a plan view of the construction of an electron-emitting device in accordance with the present invention;

FIG. 4 is a perspective view of organic gas introduction means in accordance with the present invention;

FIG. 5 is a schematic sectional view and a piping diagram of another example of the manufacturing apparatus in accordance with the present invention;

FIG. 6 is a schematic sectional view and a piping diagram of another example of the manufacturing apparatus in accordance with the present invention; and

FIG. 7 is a plan view for explaining a method of making the electron-emitting device in accordance with the present invention.

### BRIEF DESCRIPTION OF THE PREFERRED EMBODIMENTS

The present invention relates to a film forming apparatus for forming a film on a substrate, the apparatus characterized by comprising gas introduction means including a nozzle for jetting a gas for forming the film toward a surface of the substrate and an inlet for introduction of the gas, the gas introduction means having a plurality of the nozzles connected to the one inlet by divergent paths.

In the film forming apparatus according to the present invention, it is preferable that: the plurality of nozzles are positioned in one plane; the lengths of the paths from the first divergence point to the plurality of nozzles are equal to each other; the paths diverge in one plane at the divergence points; the paths diverge in one plane at the divergence points and also the plurality of nozzles are positioned in one plane; or there is provided a container placed on the substrate, the container covering the substrate to form a sealed atmosphere.

Also, the present invention relates to a film forming apparatus for forming a film on a substrate, characterized by comprising gas introduction means including a nozzle for jetting a gas for forming the film toward a surface of the substrate and an inlet for introduction of the gas, the gas introduction means having a plurality of the nozzles connected to the one inlet by divergent paths that are repeatedly divided into two in one plane.

Also, in the film forming apparatus according to the present invention, it is preferable that: the lengths of the paths from the first divergence point to the plurality of nozzles are equal to each other; the number of the nozzles is the Nth power of X (e.g. two) (N: a natural number except 0); or there is provided a container placed on the substrate, the container covering the substrate to form a sealed atmosphere.

Also, according to the present invention, there is provided a film forming method of forming a film on a substrate, the method characterized by comprising using the above-described film forming apparatus.

Also, the present invention relates to an apparatus for manufacturing an electron source in which an electron-emitting function is provided to a member provided on a substrate, the apparatus characterized by comprising gas introduction means including a nozzle for jetting a gas for providing the electron-emitting function toward a surface of the substrate and an inlet for introduction of the gas, the gas introduction means having a plurality of the nozzles connected to the one inlet by divergent paths.

Also, the present invention relates to an apparatus for manufacturing an electron source in which an electron-emitting region is formed in a conductive film provided on a substrate, the apparatus characterized by comprising energization means for causing a current to flow through the conductive film, and gas introduction means including a nozzle for jetting a gas for deoxidizing the conductive film toward a surface of the substrate and an inlet for introduction of the gas, the gas introduction means having a plurality of the nozzles connected to the one inlet by divergent paths.

Also, the present invention relates to an apparatus for manufacturing an electron source in which an electron-emitting region is formed in a conductive film provided on a substrate, the apparatus characterized by comprising energization means for causing a current to flow through the conductive film, and gas introduction means including a nozzle for jetting an organic compound gas for depositing carbon on the conductive film toward a surface of the substrate and an inlet for introduction of the gas, the gas introduction means having a plurality of the nozzles connected to the one inlet by divergent paths.

Also, in the apparatus for manufacturing an electron source according to the present invention, it is preferable that: the plurality of nozzles are positioned in one plane; the lengths of the paths from the first divergence point to the plurality of nozzles are equal to each other; the paths diverge in one plane at the divergence points; the paths diverge in one plane at the divergence points and the plurality of nozzles are positioned in one plane; the gas introduction means has a plurality of the nozzles connected to the one inlet by divergent paths that are repeatedly divided into two in one plane; the gas introduction means has a plurality of the nozzles connected to the one inlet by divergent paths that are repeatedly divided into two in one plane and the lengths of the paths from the first divergence point to the plurality of nozzles are equal to each other; the electron source has a plurality of electron-emitting devices each having a pair of opposed device electrodes, a conductive film connected to one of the device electrodes and having an electron-emitting region in its portion, and a deposit deposited on and in the vicinity of the electron-emitting region, the deposit containing at least carbon; the number of the nozzles is the Nth power of X (e.g. two) (N: a natural number except 0); there is provided a container placed on the substrate, the container covering the substrate to form a sealed atmosphere; there is provided a container placed on the substrate, the container covering the substrate except a partial region thereof to form a sealed atmosphere; there is provided a container placed on the substrate, the container covering the substrate except a partial region thereof to form a sealed atmosphere and the energization means causes a current to flow through a conductive member provided on the partial region of the substrate and connected to the conductive film.

Also, the present invention relates to a method of manufacturing an electron source comprising a step of providing an electron-emitting function to a member provided on a substrate, characterized in that the step of providing the electron-emitting function is performed by using the above-described apparatus for manufacturing an electron source.

The present invention relates to a method of manufacturing an electron source comprising a step of forming an electron-emitting region in a conductive film provided on a substrate, characterized in that the step of forming an electron-emitting region is performed by using the above-described apparatus for manufacturing an electron source.

A first embodiment mode of the present invention will be described.

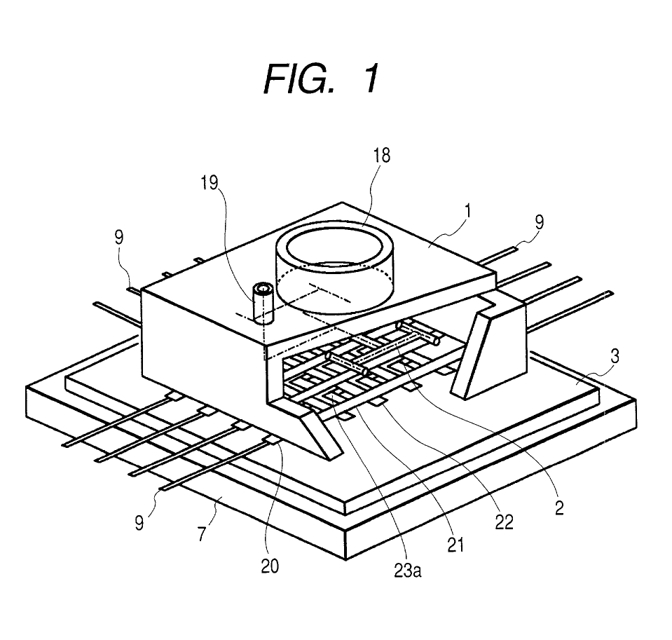

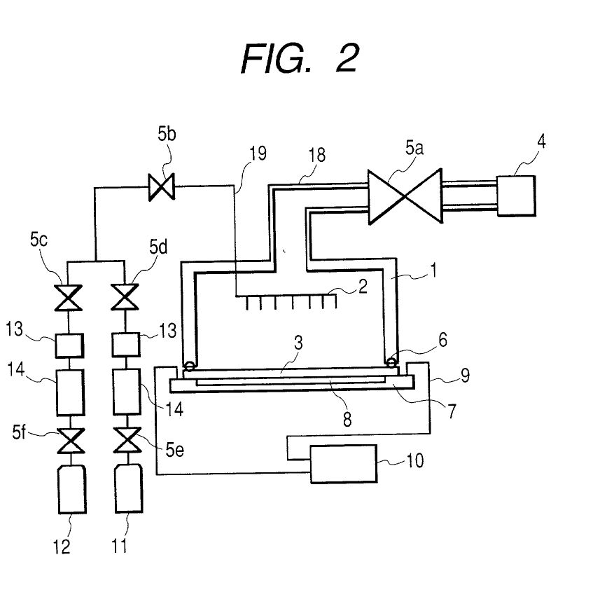

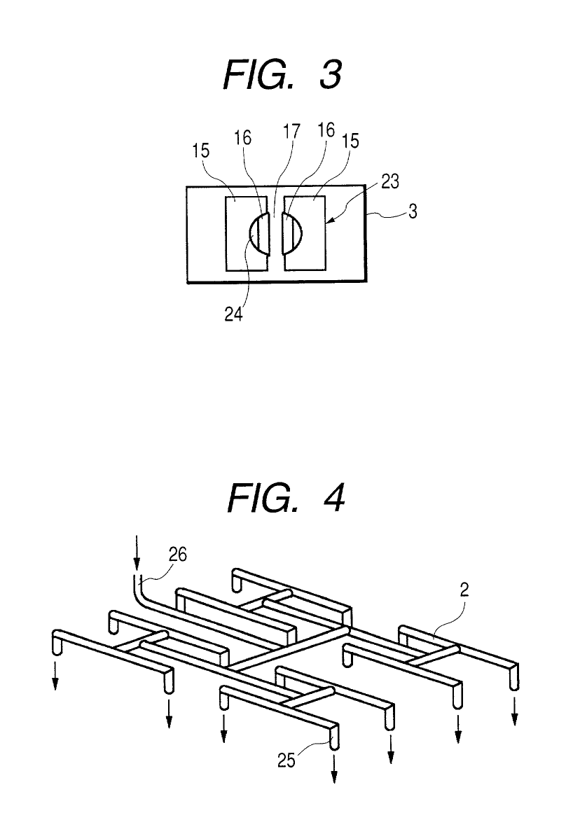

FIGS. 1 and 2 show an apparatus for manufacturing an electron source in accordance with this embodiment mode of the present invention. FIG. 1 is a perspective view of a portion of the apparatus around an electron source substrate 3, and FIG. 2 is a schematic sectional view and a piping diagram. In FIGS. 1 and 2 are illustrated: conductors 23a for forming electron-emitting devices 23 as shown in FIG. 3, an X-direction wiring 21, a Y-direction wiring 22, the electron source substrate 3, a supporting member 7, a vacuum container 1, a gas introduction pipe 19, a sealing member 6, gas introduction unit 2 for introducing an organic compound gas into the vacuum container 1, a heater 8, organic compound gas 11 contained in a gas container, a carrier gas 12 contained in a gas container, water removal filters 14, gas flow rate controllers 13, valves 5a to 5f, a vacuum pump 4, an exhaust pipe 18 connected to an exhaust opening, takeout wiring conductors 20, a driver 10 constituted of a power supply and a current control system, and a wiring 9 for connection between the takeout wiring conductors 20 and the driver 10.

The supporting member 7 supports and fixes the electron source substrate 3 and has a vacuum chucking mechanism, an electrostatic chucking mechanism, a fixing jig or the like for mechanically fixing the electron source substrate 3. The heater 8 is provided in the supporting member 7 to heat the vacuum chucking mechanism as required.

The vacuum container 1 is a container made of glass or stainless steel. As the vacuum container 1, a container made of such a material that the amount of any gas released from the container is small is preferred. The vacuum container 1 is of such a structure as to be able to cover the entire region on the electron source substrate 3 where the conductors 23a are formed except the takeout wiring conductors, and to resist pressure at least in the range from 1.33×10⁻¹ Pa (1×10⁻³ Torr) to atmospheric pressure.

The sealing member 6 is a member for maintaining the space between the electron source substrate 3 and the vacuum container 1 in a gastight condition. An O-ring, a rubber sheet or the like is used as the sealing member 6.

As the organic compound gas 11, an organic material used for activation of electron-emitting devices 23 as described below with reference to FIG. 3 or a mixed gas in which the organic material is diluted with nitrogen, helium, argon, or the like is used. When energization for forming described below with reference to FIG. 3 is performed, a gas for accelerating the formation of a fissure in a conductive film 24, e.g., a hydrogen gas having an deoxidizing effect, may be introduced into the vacuum container 1.

The organic material used for activation of the electron-emitting devices 23 may be selected from aliphatic hydrocarbons such as alkane, alkene, and alkyne, aromatic hydrocarbons, alcohols, aldehydes, ketones, amines, nitriles, and organic acids such as phenolic acid, carboxylic acid, and sulfonic acid. More specifically, a saturated hydrocarbon such as methane, ethane, or propane, which is expressed by CnH2n+2, an unsaturated hydrocarbon such as ethylene or propylene, which is expressed by a composition formula such as CnH2n, benzene, toluene, methanol, ethanol, acetaldehyde, acetone, methyl ethyl ketone, methylamine, ethylamine, phenol, benzonitrile, acetonitrile, or the like may be used.

If the organic material to be used is gaseous at ordinary temperature, it can be immediately used as the organic compound gas 11. If the organic material is a liquid or a solid at ordinary temperature, it may be used by being evaporated or sublimated in a container or, further mixed with a diluent gas. An inert gas such as nitrogen, argon or helium is used as the carrier gas 12.

The organic compound gas 11 and the carrier gas 12 are mixed at a certain ratio before being introduced into the vacuum container 1. The flow rates and the mixing ratio of the two gases are controlled by the gas flow rate controllers 13 separately provided. Each gas flow rate controller 13 is constituted by a mass-flow controller and a solenoid valve or the like. The mixed gas is introduced into the vacuum container 1 through the inlet formed in a wall portion of the vacuum container 1 after being heated to a suitable temperature by a heater (not shown) provided around the introduction pipe 19 as required. Preferably, the mixed gas heating temperature is set approximately equal to the temperature of the electron source substrate 3.

It is preferable to provide the water removal filters 14 between the gas flow rate controllers 13 and the introduction pipe 19 to remove water in the gas to be introduced. A moisture absorbent such as silica gel, a molecular sieve, or magnesium hydroxide may be used in the water removal filters 14.

The mixed gas introduced into the vacuum container 1 is exhausted at a constant exhaust rate by the vacuum pump 4 through the exhaust pipe 18 connected to the exhaust opening, thereby maintaining the pressure of the mixed gas at a certain level in the vacuum container 1. The vacuum pump 4 used in the present invention is a low vacuum pump such as a dry pump, a diaphragm pump, or a scroll pump. Preferably, an oil-free pump is used as the vacuum pump 4.

From the viewpoint of reducing the time required to complete the activation step and improving the uniformity of the result of the step, it is preferred in this embodiment mode that the pressure of the above-described mixed gas be equal to or higher than a level at which the mean free path λ of gas molecules constituting the mixed gas is sufficiently small in comparison with the inside size of the vacuum container 1. This pressure region is a so-called viscous flow region, ranging from the several hundred Pa (several Torr) to atmospheric pressure.

It is also preferred that gas introduction unit 2 be provided between the pipe 19 for introduction of the gas into the vacuum container 1 and the electron source substrate 3, because the flow of the mixed gas can be thereby controlled to uniformly supply the organic material to the entire surface of the substrate 3 so that the uniformity of electron-emitting devices 23 is high. The gas introduction unit 2 is of a piping structure as shown in FIG. 4. The gas introduction unit 2 has a gas inlet 26 in one place and a distribution path laid from the gas inlet 26 to gas nozzles 25 while being repeatedly divided into two in a plane parallel to the top surface of the electron source substrate 3 so that the path lengths from the first divergence point to the gas nozzles 25 are equal to each other. The divided distribution paths are equal to each other not only in the length to the gas nozzles 25 but also in the shape and the number of their bent piping portions. Thus, the organic compound gas can easily be distributed so that the flow rates of the gas flowing out through the gas nozzles 25 are equal to each other.

The present invention is not limited to the configuration described in this specification. The invention can also be applied to an apparatus such as a plasma CVD apparatus in which a processing gas is jetted to the entire surface of a substrate to realize a large-area film forming process.

Embodiment 1

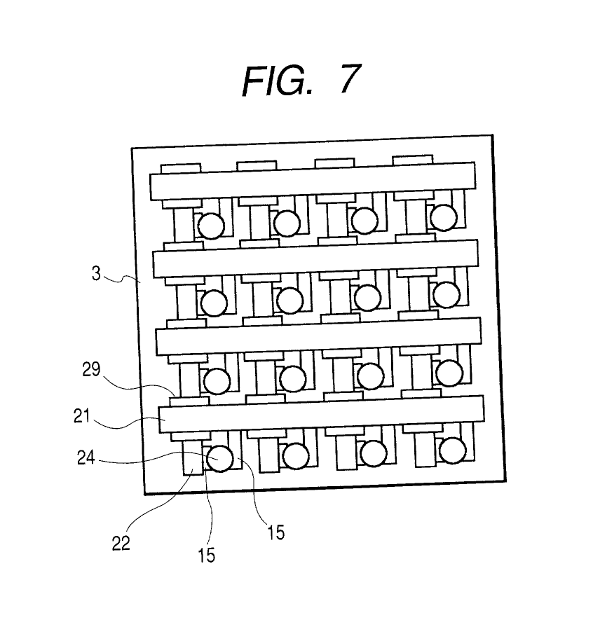

An embodiment of the present invention will be described in which an electron source, as shown in FIG. 7, having a plurality of surface conduction electron-emitting devices each formed as shown in FIG. 3 is manufactured by using the manufacturing apparatus of the present invention. In FIG. 3 are illustrated an electron source substrate 3, device electrodes 15, a conductive film 24, carbon film 16, and a gap 17 between carbon film 16 lands. Pt paste was printed on a SiO2 layer formed on a glass substrate and was heated and baked to form device electrodes 15. Also, Ag paste was printed by screen printing and was heated and baked to form an X-direction wiring 21 (240 lines) and a Y-direction wiring 22 (720 lines) as shown in FIG. 7. An insulating paste was printed at the intersections of the X-direction wiring 21 and the Y-direction wiring 22 by screen printing and was heated and baked to form an insulating layer 29.

Next, a palladium complex was applied dropwise between each pair of device electrodes 15 by using a bubble jet device and was heated to form the conductive film 24 of palladium oxide as shown in FIG. 7. In the above-described manner, the electron source substrate 3 with pairs of electrodes 15 and a plurality of conductors formed of the conductive film 24 wired in matrix form by the X-direction wiring 21 and the Y-direction wiring 22 was made.

The electron source substrate 3 thus made was fixed on a supporting member 7 of the manufacturing apparatus shown in FIGS. 1 and 2.

Next, the stainless vacuum container 1 was placed on the electron source substrate 3 with a sealing member 6 interposed therebetween and takeout wiring conductors 20 extending out of the vacuum container 1, as shown in FIG. 2. A gas introduction unit 2 as shown in FIG. 4 was placed in such a position as to face the electron source substrate 3. The gas introduction unit 2 was provided in a piping structure such as shown FIG. 4 and was formed of an aluminum pipe having a high thermal conductivity.

A valve 5a on the side of an exhaust pipe 18 connected to an exhaust opening was opened and the interior of the vacuum container 1 was evacuated by a vacuum pump 4 (scroll pump in this embodiment) to a degree of vacuum of 1.33×10⁻¹ Pa (1×10⁻³ Torr). Thereafter, to remove water considered to be attached to the exhaust device pipe and the electron source substrate, the exhaust device pipe and the electron source substrate were heated by using a piping heater (not shown) and a heater 8 for heating the electron source substrate 3 and were then gradually cooled to room temperature.

After the temperature of the substrate had been returned to room temperature, gas supply valves 5b and 5f and the valve 5a shown in FIG. 2 were opened to introduce hydrogen gas into the vacuum container 1, and a voltage was applied between the device electrodes 15 of electron-emitting devices 23 through the X-direction wiring 21 and the Y-direction wiring 22 by using a driver 10 connected to the takeout wiring conductors 20 through a wiring 9 shown in FIG. 1 to perform processes for deoxidizing and forming on the conductive film. A gap 17 was thereby formed in the conductive film 24, as shown in FIG. 3.

Subsequently, an activation process was performed by using the apparatus. The gas supply valves 5b and 5f and the valve 5a were opened to introduce a gas in which an organic compound gas 11 and a carrier gas 12 were mixed into the vacuum container 1. A nitrogen gas in which ethylene was mixed was used as the organic compound gas 11, and a nitrogen gas was used as the carrier gas 12. The opening of the valve 5a was adjusted while checking the pressure through a vacuum gage to set the pressure in the vacuum container 1 to 133×10² Pa (100 Torr).

After the introduction of the organic compound gas, a voltage was applied between the device electrodes 15 of the electron-emitting devices 23 through the X-direction wiring 21 and the Y-direction wiring 22 by using the driver 10 to perform the activation process. For activation, a method was used such that the all lines of the Y-direction wiring 22 and unselected lines of the X-direction wiring 21 were connected in common to Gnd (ground potential), ten lines of the X-direction wiring 21 were selected, and a pulse voltage was applied to one line after another. The steps of this method were repeated to perform activation with respect to all the lines in the X-direction. The device current If (current flowing between the device electrodes of each electron-emitting device) at the time of completion of activation was measured with respect to each X-direction wiring line, and the measured device current If values were compared, thereby confirming that line-to-line variation in the current was small and the result of the activation process was good.

The electron-emitting devices after the completion of the above-described activation process had the carbon film 16 lands formed thereon with the gap 17 interposed between the carbon film 16 lands, as shown in FIG. 3.

During the above-described activation process, gas analysis on the exhaust pipe 18 side was performed by using a mass spectrum measuring apparatus with a differential exhaust device not shown. The result of this analysis was that mass No. 28 of nitrogen and ethylene and ethylene fragment mass No. 26 were instantaneously increased and saturated and the values of the two masses were constant during the activation process.

Embodiment 2

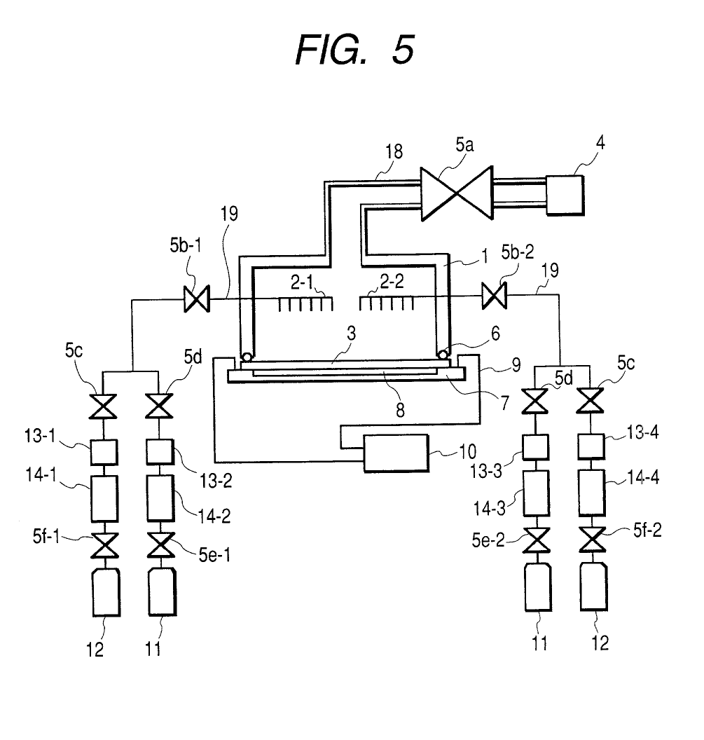

An electron source substrate 3 as shown in FIG. 7 was made as in Embodiment 1. This electron source substrate 3 was set in a manufacturing apparatus shown in FIG. 5. In this embodiment, a gas introduction unit 2 for jetting an organic compound gas as a mixed gas containing an organic material to the entire surface of the electron source substrate was divided into two units 2-1 and 2-2. This embodiment is intended for processing an electron source substrate of a larger size. If the substrate size is increased, the path lengths to nozzles 25 in the gas introduction means shown in FIG. 4 are increased. If the organic material to be used is gaseous at ordinary temperature, it can be immediately used as an organic compound gas 11. However, if the organic material is a liquid or a solid at ordinary temperature, it is evaporated or sublimated by using a heater. If the path lengths are increased, there is a risk of liquefaction in the paths of the material in the organic compound gas 11 evaporated or sublimated by the heater. The introduction units 2-1 and 2-2 were divided into two systems to avoid a considerable increase in path length. The number of systems in the gas introduction units 2-1 and 2-2, each having one common gas inlet and a plurality of nozzles communicating with the inlet may be further increased to three, four, and so on if necessary.

Except for the above, a deoxidizing process, a forming process, and an activation process were performed in the same manner as those in Embodiment 1 to make an electron source.

On each electron-emitting device after the activation process, carbon film 16 lands were formed with a gap 17 interposed therebetween, as shown in FIG. 3.

Also in this embodiment, the device current If at the time of completion of activation was measured, as in Embodiment 1. The measured variation was about 5%. The activation process was completed with improved uniformity.

Embodiment 3

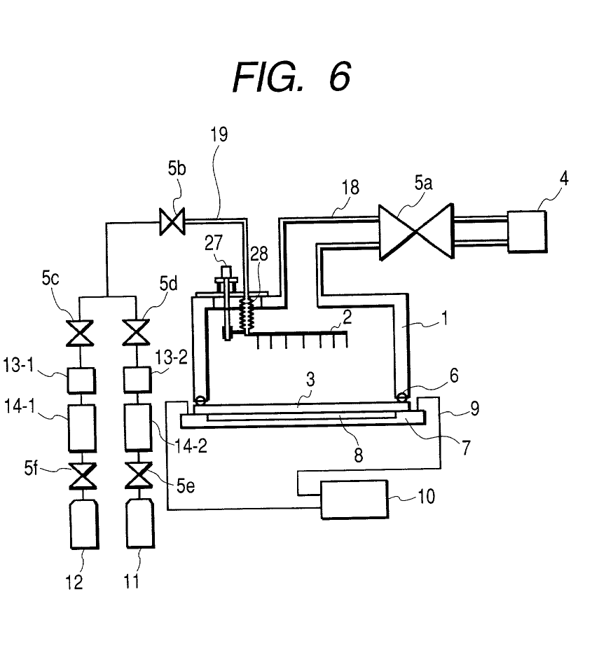

An electron source substrate 3 as shown in FIG. 7 was made as in Embodiment 1. This electron source substrate 3 was set in a manufacturing apparatus shown in FIG. 6. Referring to FIG. 6, a gas introduction unit 2 is capable of being moved in a vertical direction by a lift mechanism 27. A flexible tube 28 can extend and contract while maintaining gastightness. As nozzles 25 of the gas introduction unit 2 which are formed on the entire surface of the electron source substrate 3 are brought closer to the electron source substrate 3, the pressure distribution in the vicinity of the electron source substrate becomes worse by being influenced by the directionality (flow) of an organic compound gas. To reduce the influence of this directionality, the distance between the nozzles 25 of the gas introduction unit 2 and the electron source substrate 3 is made adjustable to a suitable height.

Except for the above, a deoxidizing process, a forming process, and an activation process were performed in the same manner as those in Embodiment 1 to make an electron source.

On each electron-emitting device after the activation process, carbon film 16 lands were formed with a gap 17 interposed therebetween, as shown in FIG. 3.

Also in this embodiment, the device current If at the time of completion of activation was measured, as in Embodiment 1. The measured variation was small. The activation process was completed with improved uniformity.

According to the present invention, a film forming apparatus capable of forming a film having improved crystallinity can be provided.

Also, according to the present invention, an electron source manufacturing apparatus can be provided which enables manufacture of an electron source having improved electron-emitting characteristics.

Also, according to the present invention, an electron source manufacturing apparatus can be provided, for forming a carbon film or carbon compound film having improved crystallinity by the electron source activation step to enable manufacture of an electron source having improved electron-emitting characteristics.

What is claimed is:

1. A film forming apparatus for forming a film on a substrate, said apparatus comprising gas introduction means including a nozzle for jetting a gas for forming the film toward a surface of the substrate and an inlet for introducing the gas, said gas introduction means having a plurality of said nozzles connected to said one inlet by divergent paths.

2. A film forming apparatus according to claim 1, wherein
a plurality of said gas introducing means are disposed at positions above a surface of the substrate, thereby uniformly jetting the gas for forming the film uniformly on the surface of the substrate.

3. A film forming apparatus according to claim 1, further comprising
a lift mechanism for moving said gas introducing means relatively to the surface of the substrate.

4. A film forming apparatus according to claim 1, wherein said plurality of nozzles are positioned in one plane.

5. A film forming apparatus according to claim 1, wherein
said one plane in which said plurality of nozzles are positioned is in parallel to the surface of the substrate.

6. A film forming apparatus according to claim 1, wherein
said plurality of nozzles have the same cross sectional areas.

7. A film forming apparatus according to claim 1, wherein
said plurality of nozzles have cross sectional areas distributed uniformly at positions above a surface of the substrate.

8. A film forming apparatus according to claim 1, wherein the lengths of said paths from the first divergence point to said plurality of nozzles are equal to each other.

9. A film forming apparatus according to claim 1, wherein said paths diverge in one plane at the divergence points.

10. A film forming apparatus according to claim 9, wherein said plurality of nozzles are positioned in one plane.

11. A film forming apparatus according to claim 1, further comprising a container placed on said substrate, said container covering said substrate to form a sealed atmosphere.

12. A film forming apparatus for forming a film on a substrate, said apparatus comprising gas introduction means including a nozzle for jetting a gas for forming the film toward a surface of the substrate and an inlet for introducing the gas, said gas introduction means having a plurality of said nozzles connected to said one inlet by divergent paths that are repeatedly divided into X in one plane.

13. A film forming apparatus according to claim 12, wherein said X is two.

14. A film forming apparatus according to claim 12, wherein the lengths of said paths from the first divergence point to said plurality of nozzles are equal to each other.

15. A film forming apparatus according to claim 14, wherein the number of said nozzles is the Nth power of X (N: a natural number except 0).

16. A film forming apparatus according to claim 12, wherein said X is two.

17. A film forming apparatus according to claim 12, further comprising a container placed on said substrate, said container covering said substrate to form a sealed atmosphere.

18. A film forming method of forming a film on a substrate, said method comprising using the apparatus according to any one of claims 1 to 17.

19. An apparatus for manufacturing an electron source in which an electron-emitting function is provided to a member provided on a substrate, said apparatus comprising gas introduction means including a nozzle for jetting a gas for providing the electron-emitting function toward a surface of the substrate and an inlet for introducing the gas, said gas introduction means having a plurality of said nozzles connected to said one inlet by divergent paths.

20. An apparatus for manufacturing an electron source in which an electron-emitting region is formed in a conductive film provided on a substrate, said apparatus comprising energization means for causing a current to flow through the conductive film, and gas introduction means including a nozzle for jetting a gas for deoxidizing the conductive film toward a surface of the substrate and an inlet for introducing the gas, said gas introduction means having a plurality of said nozzles connected to said one inlet by divergent paths.

21. An apparatus for manufacturing an electron source in which an electron-emitting region is formed in a conductive film provided on a substrate, said apparatus comprising energization means for causing a current to flow through the conductive film, and gas introduction means including a nozzle for jetting an organic compound gas for depositing carbon on the conductive film toward a surface of the substrate and an inlet for introducing the gas, said gas introduction means having a plurality of said nozzles connected to said one inlet by divergent paths.

22. An apparatus according to any one of claims 19 to 21, wherein said plurality of nozzles are positioned in one plane.

23. An apparatus according to any one of claims 19 to 21, wherein the lengths of said paths from the first divergence point to said plurality of nozzles are equal to each other.

24. An apparatus according to any one of claims 19 to 21, wherein said paths diverge in one plane at the divergence points.

25. An apparatus according to claim 24, wherein said plurality of nozzles are positioned in one plane.

26. An apparatus according to any one of claims 19 to 21, said gas introduction means has the plurality of said nozzles connected to said one inlet by divergent paths that are repeatedly divided into X in one plane.

27. An apparatus according to claim 26, wherein said X is two.

28. An apparatus according to claim 26, wherein the lengths of said paths from the first divergence point to said plurality of nozzles are equal to each other.

29. An apparatus according to claim 27, wherein said electron source has a plurality of electron-emitting devices each having a pair of opposed device electrodes, a conductive film connected to one of said device electrodes and having an electron-emitting region in its portion, and a deposit deposited on and in the vicinity of said electron-emitting region, said deposit containing at least carbon.

30. An apparatus according to claim 26, wherein the number of said nozzles is the Nth power of X (N: a natural number except 0).

31. An apparatus according to claim 30, wherein said X is two.

32. An apparatus according to any one of claims 19 to 21, further comprising a container placed on said substrate, said container covering said substrate to form a sealed atmosphere.

33. An apparatus according to claim 20 or 21, further comprising a container placed on said substrate, said container covering said substrate except a partial region thereof to form a sealed atmosphere.

34. An apparatus according to claim 33, wherein said energization means causes a current to flow through a conductive member provided on the partial region of said substrate and connected to said conductive film.

35. A method of manufacturing an electron source, comprising a step of providing an electron-emitting function to a member provided on a substrate, wherein the step of providing the electron-emitting function is performed by using the apparatus according to claim 19.

36. A method of manufacturing an electron source, comprising a step of forming an electron-emitting region in a conductive film provided on a substrate, wherein the step of forming an electron-emitting region is performed by using the apparatus according to claim 20 or 21.
